(19) United States
(12) Patent Application Publication
(10) Pub. No.: US 2011/0234313 A1
(43) Pub. Date: Sep. 29, 2011

(54) Apparatus and Method for Operating Parameter-Dependent Gain Adjustment in Radio Devices

(76) Inventors: Peter Spies, Herzogenaurach (DE); Guenter Rohmer, Erlangen (DE); Heinz Gerhaeuser, Waischenfeld (DE)

(21) Appl. No.: 12/294,681

(22) PCT Filed: Mar. 23, 2007
(86) PCT No.: PCT/EP2007/002597

§ 371 Date: Jun. 10, 2011

(30) Foreign Application Priority Data
Mar. 30, 2006 (DE) 10 2006 014 778.2

(51) Int. Cl. H03G 3/20

(52) U.S. Cl. 330/127

(57) ABSTRACT

An amplifier for an input signal Sᵢₙ, present at an input terminal, with a gain factor adjustable by a control terminal, so as to provide the amplified input signal Sᵢₙ′ at an output terminal. A decoupler is connected to the amplifier on the output side and provides a decoupling signal S_{actual} which depends on the amplified input signal Sᵢₙ′. The decoupling signal S_{actual} is processed in an analog manner, and a prepared signal S_{actual}′ is provided which is a measure of the actual output power. Comparing the prepared signal S_{actual}′ to a target value S_{target} in an analog manner yields a comparison signal S_{control} controlling the gain factor, and a target value S_{target} is a measure of the target power of the amplified input signal Sᵢₙ′. The processor is implemented to create a predetermined ratio between the target power and the actual power.

### CROSS-REFERENCE TO RELATED APPLICATIONS

This application is a National Phase of International Patent Application No. PCT/EP2007/002597 filed 23 Mar. 2007, which claims priority to German Patent Application No. 102006014778.2-35 filed 30 Mar. 2006.

### BACKGROUND OF THE INVENTION

The present invention relates to a concept for operating parameter-dependent gain adjustment in radio devices, and in particular in mobile transceivers.

Transceivers nowadays are employed in many fields, in mobile radiocommunication e.g. in DECT (digital enhanced cordless telecommunication), GSM (global system for mobile communications), UMTS (universal mobile telecommunication system), PCS (personal communication service), DCS (digital cellular system), Bluetooth, but also in transceivers for telemetry applications, for example within the ISM bands (industrial, scientific and medical bands).

In known receivers, power control operates in accordance with the principle that entire systems which contain several blocks such as transmit or receive paths are switched on or off. FIG. 4 represents, by way of example and in a simplifying manner, the structure of a known receiver e.g. for mobile radiocommunication devices as a block diagram, cf. Q4, Meinke, Grundlach, “Taschenbuch der Hochfrequenztechnik”, 5^{th} edition, Springer-Verlag. A receive antenna 400 has a radio-frequency band-pass filter 410, which restricts the signal received to the system bandwidth, connected downstream from it. The band-pass filter 410 has a radio-frequency amplifier 420, which amplifies the band-limited receive signals and feeds them to a mixer 430, connected downstream from it. An oscillator 440 or synthesizer provides the mixer 430 with a signal having the mixed frequency f₀, whereupon a signal having the intermediate frequency f_{z}, is present downstream from the mixer 430. An intermediate-frequency band-pass filter 450 now filters the signal having the intermediate frequency and performs, e.g., a channel selection. An intermediate-frequency amplifier 460 connected downstream feeds the amplified intermediate-frequency signal to a demodulator 470 (or detector), from the output terminal of which a low-frequency useful signal is forwarded to a low-frequency amplifier 480 so as to be present in an amplified state eventually.

By way of example and in a simplifying manner, FIG. 5 shows the structure of a known transmitter, for example for mobile radiocommunication devices, as a block diagram. Initially, an LF signal 500 is amplified using a preamplifier 510, and is fed to a modulator 520, cf. P. Meinke, Grundlach, “Taschenbuch der Hochfrequenztechnik”, 5^{th} edition, Springer-Verlag. Additionally, the modulator obtains, from an oscillator/synthesizer 530, a signal having the carrier frequency f₀. A radio-frequency band-pass filter 540 which filters the output signal of the modulator 520 and feeds the filtered signal to a radio-frequency power amplifier 550 is connected downstream from the modulator. The amplified signal is then emitted via the transmit antenna 560.

To save dissipated power of such transmit and/or receive arrangements, individual blocks or portions, or subsystems of same are set, unless they are immediately needed, in more power-efficient states, so-called standby states, wherein the full functionality of these blocks is no longer available, but they consume considerably less power and may be restored to full functionality relatively fast. In this manner, individual blocks and/or subsystems are activated or deactivated.

For example, during transmission, the mixer 430, the intermediate-frequency amplifiers 460 and the FM detector 470 (FM=frequency modulation), provided they exist, are deactivated. However, during reception the final transmit stage 550 and the preamplifier 510 are switched off. The oscillator/synthesizer 440/530 may be used during both operating states and may be set in a standby operating state only when neither transmission nor reception is occurring.

In the transmit/receive stages hitherto known of mobile transceivers, individual components or subsystems are thus either switched on or off, but no continuous dynamic control of functional blocks is performed. Only the gain of the intermediate-frequency amplifier (IF amplifier) as well as of the final transmit stage (PA) is partly controlled dynamically during operation. Control of the intermediate frequency amplifier is performed by measuring the receive signal strength (RSSI=receive signal strength indicator) and automatic control of the gain in accordance with the signal level received (AGC, automatic gain control). Measurement of the signal strength is performed using logarithmic amplifiers which generally consist of different numbers of limiting amplifier stages connected in series. However, these amplifiers consume a relatively large amount of dissipated power themselves, control of the IF amplifier not being conducted with the aim of reducing the power dissipation, but mainly to create as constant an input signal as possible for the subsequent components (analog/digital converter, demodulator), and to thereby limit their dynamic ranges that may be used.

What is disadvantageous about this known approach is that the individual components of transmit and/or receive arrangements for mobile radiocommunication devices need to be designed for the worst receive and transmit conditions, i.e. for the “worst case”. “Worst case” above all means the occurrence of a maximum number of adjacent channel interferers along with a minimum received power of the useful signal. For normal operation, many functional blocks are therefore overdimensioned with regard to the actual tasks and thus consume a relatively large amount of dissipated power. However, the receive signal strength may vary, for example, in DECT systems, between −94 dBm and +10 dBm, the received power reaching the minimum value only in very rare cases. Also, the adjacent channel interferers rarely arrive at the maximum values indicated in the specifications, provided that adjacent channel interferers exist at all.

In order to allow fast connection setup and permanent availability in practice, the components of the receiver need to be activated more often than those of the transmitter. Thus, the contribution of these components to the total power consumption is relatively high.

Since radio waves may propagate along different paths on their journey from a transmitter to a receiver, and may then constructively or destructively superimpose at the receiver, rapid fluctuations of the received power may result. These fluctuations change already in the case of spatial shifts in the range of, for example, half wavelengths, and are thus dependent both on the frequency and on the speed of mobile transmitters and receivers. Also, they are caused and influenced by obstacles which are moved, by reflectors, etc. within the radio hop. The currently known gain controls (for example by means of AGC arrangements) are controlled using digital circuits and microprocessors. This results in delay times due to analog/digital conversion and data processing. These systems are therefore frequently unable to react to rapid channel changes as occur within the radio channel. They are therefore frequently unable to compensate for the fast fading caused by the superposition.

A further disadvantage of hitherto known mobile radio receivers is also that for a base station search, the receiver may be active frequently, and that consequently, its operating current that may be needed is a decisive factor in the overall power budget of a radio receiver.

U.S. Pat. No. 5,311,143 discloses a circuit which enables controlling a offset (bias) of an amplifier. In this context, one uses a detector which checks a supply current of the amplifier. A supply circuit coupled to the detector then controls the offset of the amplifier in dependence on the supply current. U.S. Pat. No. 5,311,143 exhibits the problem that rapid fluctuations in a received power, which may be caused by a radio channel, for example, may indeed be offset-compensated, but cannot be eliminated. Consequently, corresponding fluctuations will remain also in the output signal of the amplifier circuit.

U.S. Pat. No. 6,642,784 B2 discloses an amplifier gain circuit for a power amplifier as occurs, for example, in final transmit stages for amplifying a transmit signal before it is emitted via a transmit antenna. The gain control further comprises a calibration circuit as well as a decoupling means which decouples, from the output signal of the amplifier, a signal component on the basis of which the gain may be controlled. However, U.S. Pat. No. 6,642,784 B2 does not address the rapid fluctuations which occur, for example, in a radio channel and are problematic during reception of radio signals. The amplifiers and amplifier circuits shown in U.S. Pat. No. 6,642,784 B2 relate to power gains as occur in radio transmitters and the concepts of which cannot directly be transferred to receive amplifiers, since in the reception of radio signals, very low levels may be amplified in a low-noise manner, the amplifiers used for this not being power amplifiers as defined by U.S. Pat. No. 6,642,784 B2.

The publication Klaus Schmalz “A 1 GHz AGC Amplifier in BiCMOS with 3 μs settling-Time for 802.11a WLAN”, Norchip Conference, 2004, in Proceedings 8-9 Nov. 2004, pages 289-292, describes a concept for controlling a gain at an intermediate frequency within a WLAN (wireless local area network) system. The concepts described there relate to WLAN systems which are designed only for restricted mobilities as occur, for example, in home applications or at airports, etc. Normally, these systems exhibit no fast fluctuations, so that gain control may occur at an intermediate frequency, for example at 810 MHz. The gain controls disclosed cannot be used for compensating for fast fading phenomena in mobile radio channels as may occur, for example, with GSM, and also cannot be used within an RF range of a radio receiver.

U.S. Pat. No. 4,422,047 discloses a radio-frequency power amplifier which amplifies a radio-frequency receive signal of a multi-channel transmitter. In this context, field-effect transistors are employed as amplifiers, signal portions being decoupled from the output signals and being fed to a frequency counter. A digital signal processing circuit then switches this signal into a corresponding band-pass filter, which suppresses broad-band noise. Additionally, the output signal of the power amplifier is sampled, so that the amplification factor of the power amplifier may be checked, particularly in order to check a standing-wave ratio at the amplifier output.

### SUMMARY

According to an embodiment, an apparatus for operating parameter-dependent gain adjustment in a radio device may have: a low-noise RF input amplifier, including a control terminal, an input terminal nd an output terminal, the amplifier being implemented to amplify an input signal Sin present at the input terminal by a gain factor adjustable via the control terminal, so as to provide the amplified input signal Sin′ at the output terminal; a decoupler connected downstream from the amplifier on the output side and implemented to provide a decoupling signal S_{actual} which depends on the amplified input signal Sᵢₙ′; a preparer n including an RMS DC converter implemented to prepare the decoupling signal S_{actual} in an analog manner in order to provide a prepared signal S_{actual}′ which is a measure of an actual power, provided by the amplifier, of the amplified input signal Sᵢₙ′; a processor implemented to compare the prepared signal S_{actual}′ to a target value S_{target} in an analog manner and to provide a comparison signal S_{control} on the basis of the comparison, the amplifier being drivable on the basis of the comparison signal at the control input for controlling the gain factor, so as to adjust a predetermined ratio between the target power and the actual power, the target value S_{target} being a measure of the target power of the amplified input signal Sᵢₙ′.

According to another embodiment, a method for operating parameter-dependent control of a gain of a radio device may have the steps of: receiving an RF input signal at an input terminal, outputting an output signal at an output terminal, and receiving a control signal at a control terminal, the RF input signal being amplified by a gain factor which corresponds to the control signal, and the output signal being output as an amplified RF input signal at the output terminal; decoupling a signal portion of the amplified RF input signal while using an RMS DC converter, the decoupled signal depending on the amplified RF input signal, preparing the decoupled amplified RF input signal in an analog manner, so that the prepared signal represents a measure of an actual power of the amplified RF input signal; processing the decoupled and prepared signal, the prepared signal being compared, in an analog manner, to a predefined target value, and a comparison signal being output on the basis of the comparison, the gain factor being controllable on the basis of the comparison signal, so as to adjust a specific ratio between the target power and the actual power.

The core idea of the present invention consists in realizing fast and power-efficient control of the receiving gain of a radio device, and in particular of a mobile receiver, e.g. a mobile radiocommunication device, in that the fast reaction times that may be needed are implemented by exclusive use of analog technology. The present invention generally relates to radio devices as occur, for example, in transmitters, receivers and transceivers in many fields, e.g. mobile radiocommunication, broadcasting, navigation, etc.

According to the invention, this is achieved by a gain device which is realized, for example, as an input amplification means which amplifies an input signal, and by a controllable amplifier. In addition, a decoupling means is connected downstream which decouples, from the amplified input signal, a signal portion (e.g. 0.1% of its power) which depends on the power of the amplified input signal, the so-called actual power, it being possible for the decoupling means to be realized by a directional coupler, for example. A preparation means then derives a measure of the actual power from the decoupled signal, it being possible to realize the derivation for example by squaring and averaging a signal portion, for example by using an RMS DC converter (RMS=root mean square, DC=direct current). A processing means now compares the signal derived from the actual power to a target value, which in turn represents a measure of the desired actual power of the amplified input signal. On the basis of this comparison, the amplifier is driven. This processing means is realized, for example, by an operational-amplifier circuit.

By means of the analog controller circuit resulting therefrom, the fluctuations caused by the radio channel may be compensated for, in accordance with the invention, in an operational parameter-adapted, fast and power-efficient manner, and the power dissipation of a receiving amplifier may thus be reduced to a minimum. The dynamic achieved by the analog technology is suitable, in particular, also for controlling input amplifiers in radio receivers. The control reduces the overall power dissipation of the radio receiver, as a result of which, in turn, e.g. longer battery runtimes in mobile receivers such as mobile telephones, PDAs, laptops, etc. may be achieved.

By employing, e.g., an RMS DC converter, a simple control loop for gain adjustment, and, thus, a reduction of the power dissipation may thus be realized, on the one hand, in accordance with the invention, and on the other hand, a power-efficient alternative to logarithmic amplifiers may be realized, since the power consumption of such inventive analog control loops itself is low compared to the savings achieved. In order to adapt the control loop to the temporal requirements entailed by the sometimes fast fluctuations within the radio channel, digital technology is dispensed with, and the controller is realized in analog technology by employing operational amplifiers. Operational-amplifier circuits in addition offer the possibility of establishing, by appropriate configuration with analog devices (such as resistive, inductive and/or capacitive elements), control characteristics which meet the respective requirements, and of controlling the active amplifiers within a receiver accordingly. By means of this control, the power consumption of these components is reduced to a minimum, and thus, the overall consumption of the receiver is also reduced.

### BRIEF DESCRIPTION OF THE DRAWINGS

Embodiments of the present invention will be detailed subsequently referring to the appended drawings, in which:

FIG. 1 shows a fundamental block diagram comprising functional blocks of the inventive apparatus for power-efficient gain adjustment in radio devices;

FIG. 2 shows a schematic representation of a potential technical realization of the inventive apparatus for power-efficient gain adjustment in radio devices, and in particular of the control loop for controlling the bias voltage/supply voltage of a low-noise input amplifier (LNA);

FIG. 3 shows a schematic representation of an alternative potential technical realization of the inventive apparatus for power-efficient gain adjustment in radio devices, and in particular of the control loop for controlling the bias voltage/supply voltage of a low-noise input amplifier (LNA);

FIG. 4 shows the fundamental architecture of a known receiver for mobile radiocommunication devices in accordance with conventional technology; and

FIG. 5 shows the fundamental architecture of a known transmitter for radio communication devices in accordance with conventional technology.

### DETAILED DESCRIPTION OF THE INVENTION

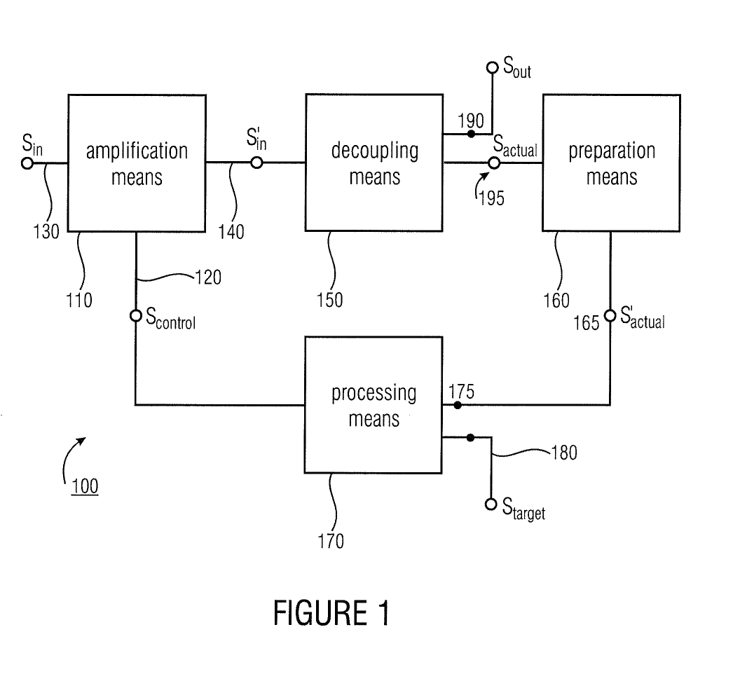

Advantageous embodiments of the inventive concept for operational parameter-dependent gain adjustment in radio devices will be explained in detail below with reference to the accompanying FIGS. 1 to 3. With regard to the following description of the advantageous embodiments of the present invention, it should be noted that identical reference numerals have been used in the entire description in the various figures for elements which are identical in function or identical or similar in action in order to simplify matters, and that these elements are thus mutually interchangeable.

The explanations which follow will be given with reference to a radio receiver, but are generally applicable to amplifier controls as are employed, for example, in receiving amplifiers, transmitting amplifiers, intermediate-frequency amplifiers, etc. The present invention generally relates to radio devices, i.e. transmitters, receivers and transceivers as are employed in many fields such as mobile radiocommunication, broadcasting, telemetry, navigation, etc.

The structure of a controller circuit for power-efficient control of a radio receiver in accordance with a first embodiment of the present invention shall be explained in detail below by way of example with reference to FIG. 1, FIG. 1 initially fundamentally explaining the principle in the form a block diagram.

FIG. 1 shows a section of a fundamental radio receiver 100 with the controller circuit for operating parameter-dependent gain adjustment in accordance with the present invention. The signals described below refer to the operating state of the inventive radio device 100. The radio device 100 consists of a amplification means 110, which may be realized, for example, as an input amplification means (input stage), comprising a control terminal 120 having a control signal S_{control} applied thereat, an input terminal 130 having an input signal Sᵢₙ applied thereat, and an output terminal 140 having an output signal Sᵢₙ′ applied thereat which corresponds the amplified input signal Sᵢₙ. It is via the control terminal 120 that a gain factor by which the input signal Sᵢₙ applied at the input terminal 130 is amplified, is predefined for the amplification means 110 comprising the control signal S_{control}, the amplified input signal Sᵢₙ′ being provided, or output, at the output terminal 140.

On the output side, the amplification means 110 has a decoupling means 150 connected downstream from it. The decoupling means 150 has two output terminals 190 and 195. The decoupling means 150 decouples a decoupling signal S_{actual}, which is dependent on the output signal Sᵢₙ′ of the amplification means 110, from said output signal Sᵢₙ′, and outputs it at the output terminal 195, i.e. the decoupling signal S_{actual} has a predetermined or known ratio to the output signal Sᵢₙ′ of the amplification means 110, or to the power of the output signal Sᵢₙ′. The output signal Sₒᵤₜ is provided at the output terminal 190 of the decoupling means 150. A preparation means 160 is connected downstream from the decoupling means 150. The preparation means 160 prepares the decoupling signal S_{actual}, which is provided by the decoupling means 150, in an analog manner, and provides a prepared decoupling signal S_{actual}′ at its output terminal 165, said decoupling signal S_{actual}′ being a measure of the power output by the amplification means 110, the so-called actual power of the amplified input signal Sᵢₙ′.

The processing means 170 is connected downstream from the preparation means 160. The processing means 170 comprises a first input terminal 175 and a second input terminal 180. The processing means 170 determines, for example by means of a comparison, a control signal S_{control}, which in turn is forwarded to the control input 120 of the amplification means 110, from the signal S_{actual}′ obtained from the preparation means 160 at the first input terminal 175, and from the target value S_{target} obtained at the second input terminal 180 which represents a measure of the actual power desired. At its output terminal, the processing means 170 controls the control signal S_{control} such that a specific ratio results between the target value S_{target} and the prepared decoupling signal S_{actual} of the preparation means 160. Typically, the difference between the output value S_{actual}′ of the preparation means 170 and the target value S_{target} is compensated for, so that ideally, S_{actual}′=S_{target}. Optionally, controlling a specific control deviation ΔS is also feasible (ΔS=S_{actual}′−S_{target}). The processing means 170 controls the control input 120 of the amplification means 110 and thereby adjusts the gain factor thereof. The controlled output signal Sₒᵤₜ will then be present at the output terminal 190 of the gain control, i.e. of the inventive radio amplifier.

In accordance with the inventive concept for power-efficient gain adjustment, one exploits, in accordance with the invention, the property that with electronic amplifiers, their functional parameters such as gain, linearity and noise behavior may be altered or adjusted in dependence on the value of an operating parameter, e.g. their supply voltage or a bias voltage. Likewise, the current consumption changes in dependence on the supply voltage or the bias voltage. Thus, for example, gain and linearity are proportional to the value of a supply current. A typical general example of an operating parameter-dependent amplifier is a differential amplifier.

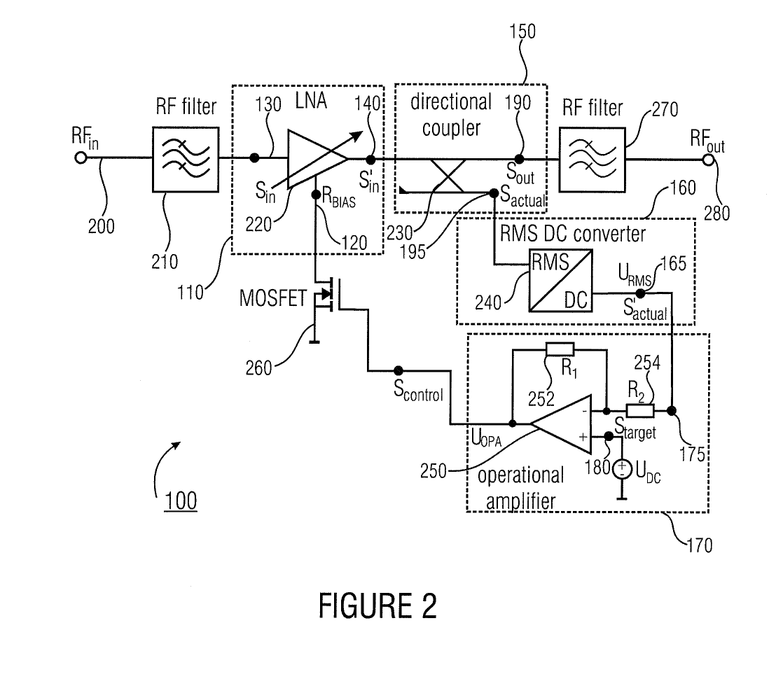

On the basis of FIG. 2, potential technical realization of the embodiment the principle of which is presented in FIG. 1 shall be explained below in detail. To simplify matters, the functional blocks and the associated reference numerals of FIG. 1 have been included in the drawing.

The signals described below again relate to the operating state of the inventive radio device 100. The realization, depicted in FIG. 2, of an inventive radio device shows an RF input signal RFᵢₙ at an input terminal 200, an optional radio-frequency band-pass filter 210, a receiving amplifier 220 which is advantageously low in noise, may be controlled via a resistor R_{BIAS}, realizes the amplification means 110, and may also be implemented, in accordance with the invention, as an input amplifier, a directional coupler 230 representing the decoupling means 150, an RMS DC converter 240 realizing the preparation means 160, an operational amplifier 250 comprising two configured resistive elements 252 and 254 comprising resistances R₁ and R₂, which correspond to the processing means 170, and a metal oxide layer field-effect transistor 260 (MOSFET), the MOSFET representing a resistance R_{BIAS} which may be controlled with respect to a reference potential (e.g. ground). Optionally, the MOSFET may also be realized, in accordance with the invention, by several MOSFETs or other transistor means (e.g. one or several bipolar transistors or, generally, field-effect transistors). In addition, FIG. 2 shows a second optional radio-frequency filter 270 and the output terminal 280 where the radio-frequency output signal RFₒᵤₜ is output.

Generally, low-noise receiving amplifiers 220, so-called low-noise amplifiers (LNA), which are typically arranged close to the receive antenna in the receive path, are employed in radio devices 100. These amplifiers 220 are characterized by small noise figures. Typical values of the noise figures range between 1 and 5 dB and vary depending on the bandwidth supported (e.g. 5 dB for a bandwidth of 2-20 GHz), the gain factors typically range from about 10-40 dB.

The low-noise input amplifier 220 (LNA) has a decisive influence on the noise performance of the entire receiver 100. In accordance with the invention, one exploits the fact that various known LNA implementations offer the possibility of adjusting, and in particular of reducing, the gain and simultaneously the current consumption of the component by means of a control signal S_{control} present at the control terminal 120, i.e. that the LNA 220 may thus also be controlled in a operational parameter-dependent manner. The gain may be preset at this terminal 120 by an external resistive element. If a resistive element comprising an adjustable resistance, such as a transistor 260, is used, the gain may be varied, during operation, via the control voltage of the transistor 260. Generally, it is naturally also feasible for the transistor 260 to be included or integrated into the LNA 220, so that the LNA 220 could be controlled directly by the OPA circuit 250 by means of the control signal S_{control}.

The inventive mode of operation and control consists in that for controlling such an LNA 220, a directional coupler 230 decouples a defined portion S_{actual} of the output signal Sᵢₙ′ of the LNA 220, any decoupling elements generally being feasible, such as (also inductively, capacitively) via a shunt resistor, a directional coupler, etc. This portion S_{actual} of the signal Sᵢₙ′ is now fed to an RMS DC converter 240. Within the RMS DC converter 240, a direct-current signal S_{actual}′ is generated from the decoupled signal S_{actual} in accordance with the root mean square method (RMS). This value represents a measure of the actual power of the signal Sᵢₙ′ downstream from the amplifier 220, other evaluation networks are also feasible, in principle, such as a further OPA circuit squaring and averaging an input signal. An output signal S_{actual}′ (U_{RMS}) of the RMS DC converter 240 which is proportional to the power of the amplified input signal Sᵢₙ′ is fed to the controller, which consists of the OPA 250 (operational amplifier) having additional configurations. The OPA configured as an inverting subtractor generates the drive signal S_{control}=U_{OPA} for the transistor 260 in accordance with the following formula:

$${U}_{OPA} = {U}_{DC} \cdot ( 1 + \frac{{R}_{1}}{{R}_{2}} ) - {U}_{RMS} \cdot \frac{{R}_{1}}{{R}_{2}} , with {U}_{OPA} \hat{=} {S}_{control} , \\ {U}_{DC} \hat{=} {S}_{target} , {U}_{RMS} \hat{=} {S}_{acutal}^{′} .$$

The OPA 250 here is implemented as an inverting subtractor, for example, by being configured with the two resistive elements 252 and 254 comprising the resistances R₁ and R₂, and thus realizes the controller of the control loop. In principle, other OPA circuits and, thus, other realizations of controllers are also possible, e.g. integrative or differential controllers, the present invention using analog and, thus, fast devices.

One may see from this relationship that when the signal power and, thus, the output voltage U_{RMS}=S_{actual}′ of the RMS DC converter 240 is increased, the output signal Uₒₚₐ=S_{control} of the OPA 250 decreases. With this signal Uₒₚₐ, the transistor means 260, or the LNA 220, is controlled via S_{control} and thus, the gain and, consequently, the supply current is controlled. It would also be feasible, for example, that the target value for the gain control is predefined in dependence on a bit error rate as could be determined by a baseband processor, for example. The bit error rate may be determined after demodulation in the baseband, i.e. on the basis of the useful signal. A detector/estimator estimates, on the basis of the symbols received, the data transmitted, which is then fed to a decoder. The codes used in current radio systems enable determining a bit error rate or block error rate, for example via check sums. The bit error rate or block error rate is determined within the baseband by a decoder. If the bit error rate exceeds a predefined measure, typical values being 1-2%, the target value of the gain adjustment may be increased, whereupon the power made available will also increase. By an increase in the power, the signal/noise ratio and, thus, the bit error rate or block error rate, in turn, are improved. An increase in the gain of the receiving amplifier will thus result in a decrease in the bit error rate. In accordance with this principle, input gain adjustment controlled by bit errors is also possible in accordance with the invention.

By further configuring the OPA with capacitors or other discrete devices, the dynamics of the controller circuit may be influenced. In this manner, various controller types may be realized. In accordance with the requirements of the controller circuit, various controllers such as P controllers (P=proportional), PD controllers (PD=proportional differential), PID controllers (PID=proportional differential integrative), etc. may be employed.

For example, the fluctuations caused by the mobile radio channel highly depend on the speed of the mobile stations, and are thus smaller in systems which are mainly used in home applications (e.g. DECT) than in mobile radio systems, which are also employed, for example, along roads and railway tracks (e.g. GSM, UTMS). This is why the requirements placed upon the controller circuit vary depending on the field of use, and may be taken into account in any realization.

In accordance with the invention, the gain of the amplification means 110 implemented as an LNA is adapted to the current requirement and, thus, to the radio channel, as a result of which the power dissipation of the receiver 100 decreases. In accordance with the invention, a controller circuit is thus used for controlling a supply voltage or bias voltage of the amplifier. In accordance with the first realization of the invention, this controller circuit comprises a coupling element such as a directional coupler 230, an RMS DC converter 240, and an operational amplifier 250. The coupling element 230 decouples a portion, which is small in comparison to the actual power, of the signal S_{actual}′. Subsequently, the signal is processed further within an operational-amplifier circuit 250 (OPA). The OPA circuit 170 creates a control signal S_{control} for the amplifier 220 within the receiver 100 such that an increase in the signal power entails a reduction in the gain of the receiver 100. This may also occur via the supply voltage or bias voltage. By means of the gain adapted to the requirements, the supply current of the amplifier 220 is also reduced. The target value S_{target} for the power of the output signal of the controlled amplifier 220 may be adjusted by means of a direct voltage U_{DC} at the positive input terminal 180 of the OPA. In this manner, this controller circuit may be employed for any amplifiers 220.

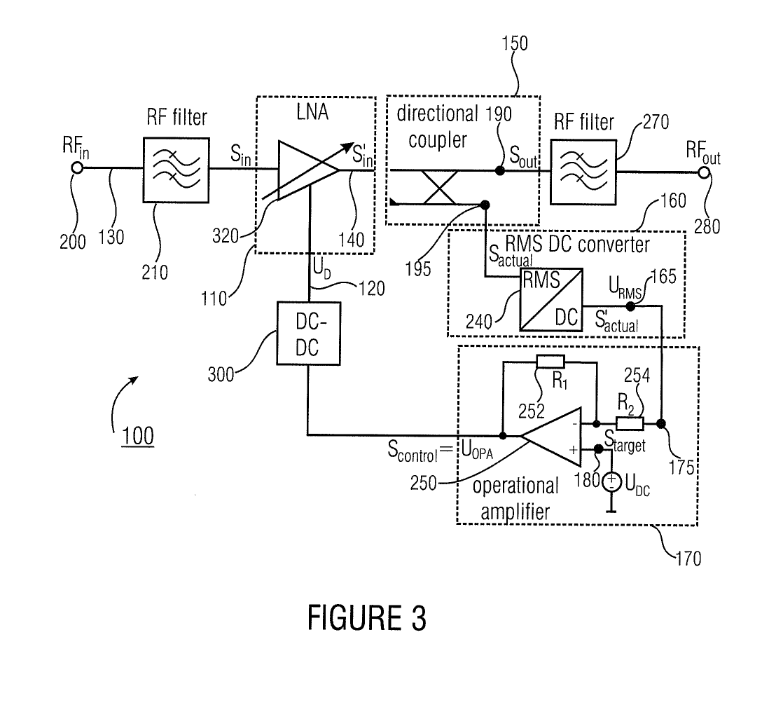

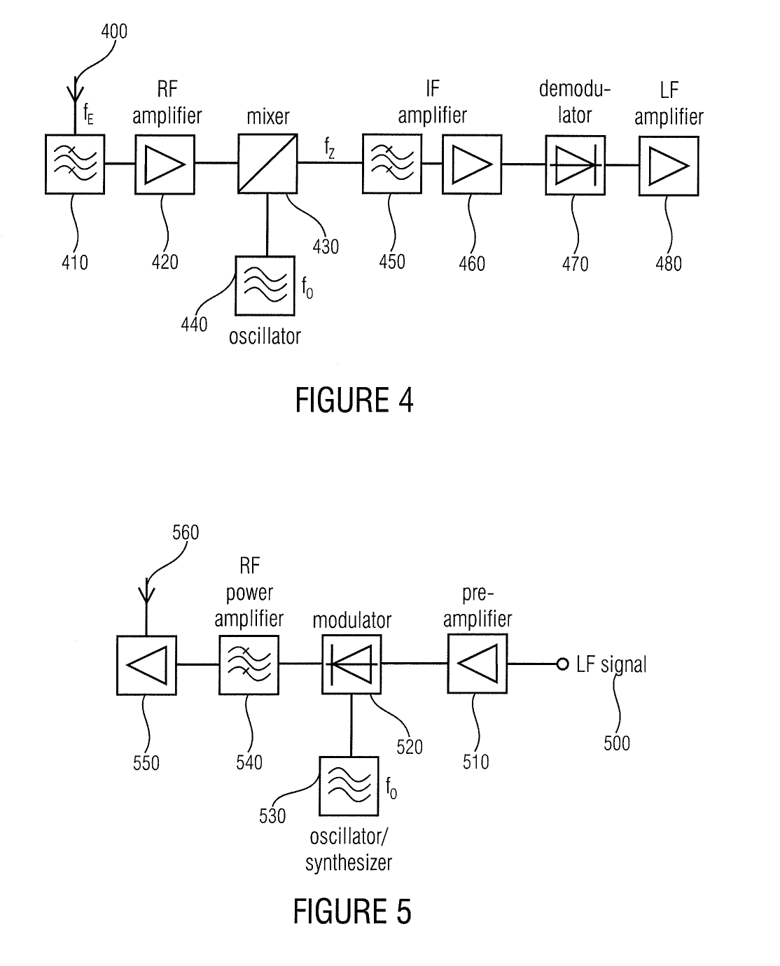

FIG. 3 shows a further inventive realization of a circuit for power-efficient gain adjustment of a radio device 100, which here is represented as a radio receiver. A difference as compared to the realizations in FIG. 2 is that the supply voltage of an input amplifier 320, which advantageously is again realized as an LNA, is now controlled via a DC/DC converter 300. Association with the fundamental functional blocks in accordance with FIG. 1 is again indicated by dashed-line blocks. The above explanations are thus also applicable to the remaining functional blocks and circuit elements and, similarly, to the receiver circuit 100 of FIG. 3.

As is depicted in FIG. 3, an adjustable voltage controller 300 (DC/DC converter=direct current/direct current) may be controlled, in accordance with the invention, using the output signal S_{control} of the OPA 250, said voltage controller 300 providing a defined output voltage U_{DC} in dependence on an input signal S_{control}. The supply voltage thereof would be controlled as a function of the RMS value S_{actual}′=U_{RMS} of the amplifier output signal. If with the amplifier, there is a connection between supply voltage, gain, and supply current, a reduction of the power consumption may also be achieved by a gain reduction at the input amplifier 320.

The DC/DC converter 300 could also be integrated into the LNA 320, and the latter could thus be directly controlled by the OPA circuit 250. It is also feasible for the DC/DC converter 300 to be integrated into the LNA 320 in a merely functional manner, and for the LNA 320 now to adjust its gain depending on its supply voltage, in accordance with a characteristic. In principle, many drive components or adaptation networks between the OPA circuit 250 and the LNA 320 are feasible, it being possible for these adaptations to be also integrated both into the LNA 320 and into the OPA circuit 250. Advantageously, the invention relates to LNAs, but other amplifier realizations 110 are also feasible in accordance with the invention, of course.

Within the framework of the present invention in accordance with FIGS. 1-3, the dynamics of the controller circuit may be influenced by further configuring the OPA 250 with capacitors, inductances, etc. In this manner, different controller types may be realized. In accordance with the requirements of the controller circuit, various controllers such as P controllers, PD controllers, PID controllers, etc. may be employed.

In addition, it is possible to decouple the signal power S_{actual} not directly downstream from the LNA 220/320, but downstream from the channel filter 270 or at a later point of the receive chain. Thus, interference signals outside the desired frequency band do not influence the gain of the controlled components. As a result, the input power of the RMS DC converter is higher, and so is its measurement accuracy.

It is also possible, on the basis of the power of a single channel, to control the power of an entire transmission band, which contains several channels, via the target value of the gain control. For example, the power of one single channel may be used representatively for controlling the powers of all channels. Examples are broadcast receivers which receive an entire spectrum of channels (e.g. TV channels). In such a case it is assumed that several channels, which are adjacent to one another within the frequency range, find the same propagation conditions within the mobile radio channel. A broadcast receiver may now readjust, on the basis of the power of a single channel, the power of a group of channels within a specific bandwidth. This method may be employed wherever a channel may be employed as a representative of a group of channels, for example also in mobile radiocommunication, when, e.g., several channels are associated with one user in order to increase the user data rate.

A further variant of efficient gain adjustment on the basis of operating parameters would be control based on interference signals. In such a case, the interference signals are then decoupled, and the amplifier power is controlled in accordance with the interference power. In this context, adjacent channels are initially selected using filters, and the power is measured there using an RMS DC converter. So as not to overload subsequent amplifier stages, the gain may be reduced now if a correspondingly high power has been measured on the adjacent channels. Specifically in the radio-frequency range and in the gain stages employed there is it important to operate same within their operating range envisaged. If such an amplifier is driven to the limit of its power range, saturation effects will occur. These effects will give rise to distortions in the waveform, several simultaneous signals will result in intermodulation products. To avoid such a high level of drive of an amplifier, it is important for its input signal to be controlled to the operating range of the amplifier.

Realization of the present invention is able to achieve this. On the basis of the power in an entire input band or, representatively, in a single channel or an adjacent channel, the power in the entire transmission band could be determined, and could be controlled to the input range of an amplifier stage by means of the inventive control for operating parameter-dependent gain adjustment.

In summary it may be stated that the inventive realization of the power-efficient gain adjustment of radio devices operates amplifiers at lower powers, and that they thus consume less dissipated power. By using the RMS DC converters, the signal power may be measured at any sites of the receiver path in a simple, low-cost and power-efficient manner. By using purely analog circuits, this controller circuit may also react to fast signal changes, and thus increases the saving potential with strong signals and, thus, reduced gain. Controlling the amplifier of a radio device may thus occur, in accordance with the invention, with the goal of power reduction.

The inventive concept is applicable both to receivers or receive means, to transmitters or transmit means, and to transceivers. The inventive operating parameter-dependent control may also be employed for controlling a transmit amplifier. Since the fluctuations caused by the mobile radio channel are not yet known at a transmitter, they may be reported, for example, by the receiver via a feedback channel. On the basis of this feedback, the transmitter may now control its power. In addition, a combination of the inventive apparatus within a transmitter and a receiver would also be feasible. In this case, the receiver would use an inventive operating parameter-dependent control for gain adjustment at a receive amplification means, and the transmitter would use an inventive operating parameter-dependent control for gain adjustment of its transmit amplifier. In this scenario, too, it would be feasible for the receiver to transmit, to the transmitter, information regarding the gain adjustment or regarding the power fluctuations caused by the mobile radio channel.

The inventive concept for operating parameter-dependent gain adjustment is advantageous both for stationary radio devices and for mobile radio devices. In a transmit means, the inventive control for gain adjustment may reduce not only the power consumption, but, consequently, also thermal stress, for example of a final transmit stage. By analogy with a receive means, in the transmit means the transmit power is adapted to the channel properties, and consequently, one uses only so much transmit power as is currently needed. As a result, the thermal load of a transmitter is reduced to a more efficient amount. The above advantages achieved by gain adjustment tailored to the requirements are also found, by analogy therewith, in transceiver devices, or transceivers.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. An apparatus for operating parameter-dependent gain adjustment in a radio device, comprising:
a low-noise RF input amplifier, comprising a control terminal, an input terminal nd an output terminal, the amplifier being implemented to amplify an input signal Sin present at the input terminal by a gain factor adjustable via the control terminal, so as to provide the amplified input signal Sin′ at the output terminal;
a decoupler connected downstream from the amplifier on the output side and implemented to provide a decoupling signal S_{actual} which depends on the amplified input signal Sᵢₙ′;
a preparer comprising an RMS DC converter implemented to prepare the decoupling signal S_{actual} in an analog manner in order to provide a prepared signal S_{actual}′ which is a measure of an actual power, provided by the amplifier, of the amplified input signal Sᵢₙ′;
a processor implemented to compare the prepared signal S_{actual}′ to a target value S_{target} in an analog manner and to provide a comparison signal S_{control} on the basis of the comparison, the amplifier being drivable on the basis of the comparison signal at the control input for controlling the gain factor, so as to adjust a predetermined ratio between the target power and the actual power, the target value S_{target} being a measure of the target power of the amplified input signal Sᵢₙ′.

2. The apparatus as claimed in claim 1, wherein the decoupler comprises a directional coupler for decoupling a decoupling signal S_{actual} dependent on the actual power of the amplified input signal Sᵢₙ′.

3. The apparatus as claimed in claim 1, wherein the preparer prepares the decoupling signal S_{actual} such that it represents a measure of the actual power output by the amplifier.

4. The apparatus as claimed in claim 3, wherein the decoupled signal S_{actual} is squared and averaged, so that S_{actual}′ comprises an averaged value which is proportional to the actual power output by the amplifier.

5. The apparatus as claimed in claim 1, wherein the preparer comprises an RMS DC converter, the RMS DC converter being implemented to square and to average the decoupling signal S_{actual} so as to provide the squared and averaged decoupling signal S_{actual}′ at its output terminal.

6. The apparatus as claimed in claim 1, wherein the processor comprises an operational-amplifier circuit.

7. The apparatus as claimed in claim 6, wherein the operational-amplifier circuit comprises a differential-amplifier circuit.

8. The apparatus as claimed in claim 1, wherein the gain of the amplifier is adjustable via a resistive element comprising a controllable resistance, R_{BIAS}, at the control terminal.

9. The apparatus as claimed in claim 8, wherein the resistive element comprises a transistor, the processor driving the transistor using a control signal S_{control} so as to adjust a resistance with respect to a reference potential.

10. The apparatus as claimed in claim 1, wherein the gain of the amplifier is adjustable via a supply voltage U_{D} at the control terminal.

11. The apparatus as claimed in claim 10, wherein the processor is implemented to adjust the supply voltage at the control terminal of the amplifier by the processor via a controllable voltage converter.

12. The apparatus as claimed in claim 1, wherein the target value S_{target} is proportional to the target power desired.

13. The apparatus as claimed in claim 1, wherein the processor is implemented to control the actual power to be equal to the target power, within a tolerance range.

14. The apparatus as claimed in claim 1, wherein the radio device is a mobile radiocommunication device.

15. The apparatus as claimed in claim 1, wherein the radio device is a transmitter, a receiver or a transceiver.

16. A method for operating parameter-dependent control of a gain of a radio device, comprising:
receiving an RF input signal at an input terminal, outputting an output signal at an output terminal, and receiving a control signal at a control terminal, the RF input signal being amplified by a gain factor which corresponds to the control signal, and the output signal being output as an amplified RF input signal at the output terminal;
decoupling a signal portion of the amplified RF input signal while using an RMS DC converter, the decoupled signal depending on the amplified RF input signal, preparing the decoupled amplified RF input signal in an analog manner, so that the prepared signal represents a measure of an actual power of the amplified RF input signal;
processing the decoupled and prepared signal, the prepared signal being compared, in an analog manner, to a predefined target value, and a comparison signal being output on the basis of the comparison, the gain factor being controllable on the basis of the comparison signal, so as to adjust a specific ratio between the target power and the actual power.

17. The method as claimed in claim 16, wherein the ratio between the actual power and the target power is adjusted, within a tolerance range, such that the actual power and the target power are identical.
